(19) United States
(12) Patent Application Publication
(10) Pub. No.: US 2010/0110786 A1
(43) Pub. Date: May 6, 2010

(54) Nonvolatile memory device, memory system including the same, and memory test system

(75) Inventors: Dongku Kang, Yongin-si (KR); Sungsoo Lee, Seongnam-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/585,870

(22) Filed: Sep. 28, 2009

(30) Foreign Application Priority Data
Oct. 31, 2008 (KR) 10-2008-0107854

(51) Int. Cl. G11C 16/06; G11C 7/04; G11C 5/14; G11C 7/06; G11C 29/00

(52) U.S. Cl. 365/185.2; 365/211; 365/189.09; 365/189.07; 365/201

(57) ABSTRACT

Provided are a nonvolatile memory device and a memory test system. The nonvolatile memory device includes a temperature compensator to calculate a trim value for regulating a characteristic of the nonvolatile memory device that varies with temperature in response to a test signal. The memory test system includes a plurality of nonvolatile memories and a tester. Each of the nonvolatile memories includes a temperature compensator. The tester tests the plurality of nonvolatile memories. The temperature compensator calculates a trim value for regulating a characteristic of the nonvolatile memory device that varies with temperature in response to a test signal of the tester.

### PRIORITY STATEMENT

This U.S. non-provisional patent application claims priority under 35 U.S.C. §119 to Korean Patent Application No. 10-2008-107854, filed on Oct. 31, 2008, in the Korean Intellectual Property Office (KIPO), the entire contents of which are hereby incorporated by reference.

### BACKGROUND

Example embodiments relate to a nonvolatile memory device, a memory system including the same, and a memory test system.

When semiconductor chips are fabricated on a wafer, an Electrical Die Sort (EDS) test is performed to test electrical characteristics of the semiconductor chips on the wafer prior to a packaging process.

### SUMMARY

Example embodiments provide a nonvolatile memory device and a memory test system capable of reducing test time.

Example embodiments provide nonvolatile memory devices including a temperature compensator automatically calculating a trim value for regulating a characteristic of the nonvolatile memory device that varies with temperature in response to a test signal.

In example embodiments, the temperature compensator may include a trim logic circuit to receive the test signal and calculate the trim value and a temperature sensor to generate a voltage based on the trim value and a sensed temperature. The trim logic circuit increases the trim value until the voltage is equal to a target value.

In example embodiments, the temperature compensator may further include an analog-digital converter to convert the voltage into a digital value and a storage to store the trim value when the digital value is equal to a target digital value corresponding to the target value. The trim logic circuit increases the trim value if the digital value is not equal to the target digital value corresponding to the target value.

In example embodiments, the temperature compensator may further include a reference circuit to generate a trim up signal based on the voltage and a reference value corresponding to the target value. The trim logic circuit increases the trim value based on the trim up signal.

In example embodiments, the trim value may be increased less than a threshold number of times.

In example embodiments, the temperature sensor may include a reference voltage generator to generate a reference voltage corresponding to the trim value and a comparator to generate the voltage based on the reference voltage and a threshold voltage that varies with temperature.

In example embodiments, the nonvolatile memory device may include a NAND flash memory. The temperature compensator may correct a word line voltage of the NAND flash memory according to temperature.

In example embodiments, the trim value may be calculated during wafer level test operation.

In example embodiments, memory systems include a nonvolatile plurality of memory devices including a temperature compensator to calculate a trim value for regulating a characteristic of the plurality of nonvolatile memory devices that varies with temperature in response to a test signal and a memory controller controlling the nonvolatile memory device.

In example embodiments, memory test systems include a plurality of nonvolatile memories, each having a temperature compensator and a tester to test the plurality of nonvolatile memories. The temperature compensator calculates a trim value for regulating a characteristic of the plurality of nonvolatile memories that varies with temperature in response to a test signal.

### BRIEF DESCRIPTION OF THE DRAWINGS

Example embodiments will be more clearly understood from the following brief description taken in conjunction with the accompanying drawings. FIGS. 1-9 represent non-limiting, example embodiments as described herein.

FIG. 1 is a diagram illustrating a memory test system according to an example embodiment.

FIG. 2 is a diagram illustrating a temperature compensator of FIG. 1 according to an example embodiment.

FIG. 3 is a diagram illustrating a temperature compensator of FIG. 1 according to an example embodiment.

FIG. 4 is a diagram illustrating a temperature sensor according to an example embodiment.

FIG. 5 is a diagram illustrating regulation of an offset voltage of the temperature sensor of FIG. 4.

FIG. 6 is a flowchart illustrating a method of calculating a trim value of a temperature compensator in a memory test system according to an example embodiment.

FIG. 7 is a diagram illustrating a NAND flash memory having a temperature compensator according to an example embodiment.

FIG. 8 is a diagram illustrating an example of using the temperature compensator of FIG. 7 according to an example embodiment.

FIG. 9 is a diagram illustrating a Solid State Drive (SSD) system including a flash memory device according to an example embodiment.

It should be noted that these Figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION OF EXAMPLE EMBODIMENTS

Example embodiments will now be described more fully with reference to the accompanying drawings, in which example embodiments are shown. Example embodiments may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

A memory test system according to an example embodiment may include nonvolatile memories configure to automatically calculate trim values for regulating an offset of a temperature compensator in a test mode. The memory test system may process in parallel a plurality of nonvolatile memories during test operation. Thus, test time may be shortened compared to typical test operations.

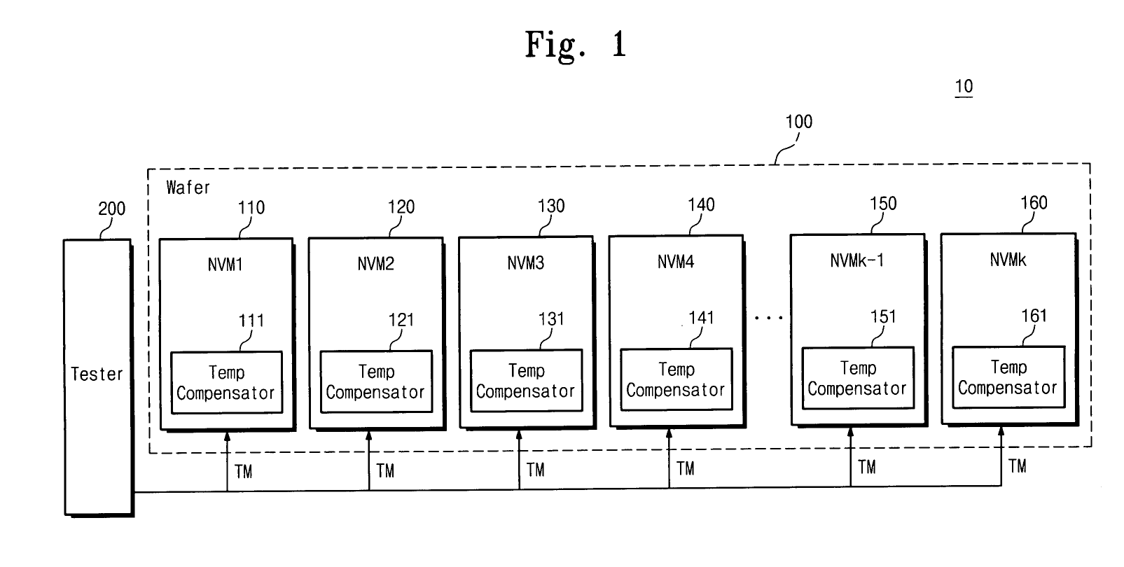

FIG. 1 is a diagram illustrating a memory test system according to an example embodiment. Referring to FIG. 1, a memory test system 10 may include a wafer 100 having a plurality of nonvolatile memories 110, 120, 130, . . . , 160, and a tester 200 simultaneous performing a parallel test with respect to the plurality of nonvolatile memories 110, 120, 130, . . . , 160.

The nonvolatile memories 110, 120, 130, . . . , 160 may include temperature compensators 111, 121, 131, . . . , 161 automatically performing a trimming operation in response to a test signal TM. The trimming operation is a process of calculating trim values to align the offsets of the temperature compensators 111, 121, 131, . . . , 161 of the plurality of nonvolatile memories 110, 120, 130, . . . , 160.

The temperature compensators 111, 121, 131, . . . , 161 may be used to correct variations of the nonvolatile memories 110, 1210, 130, . . . , 160 with temperature. For example, a read, a program or delete voltage may be included in the variation with temperature. The nonvolatile memories 110, 120, 130, . . . , 160 may be implemented to correctly read out stored values by compensating the read voltage according to temperature. The temperature compensators 111, 121, 131, . . . , 161 may perform correction according to temperature in a circuit.

However, because the temperature compensators 111, 121, 131, . . . , 161 are analog circuits, they may not have the same characteristics in terms of manufacturing process. Accordingly, the temperature compensators may require a trimming process to have uniform characteristics. For example, offset values are required to be identical. The trimming process may be performed in the temperature compensator 111, 121, 131, . . . , 161 of the nonvolatile memories 110, 120, 130, . . . , 160 during wafer level test operation.

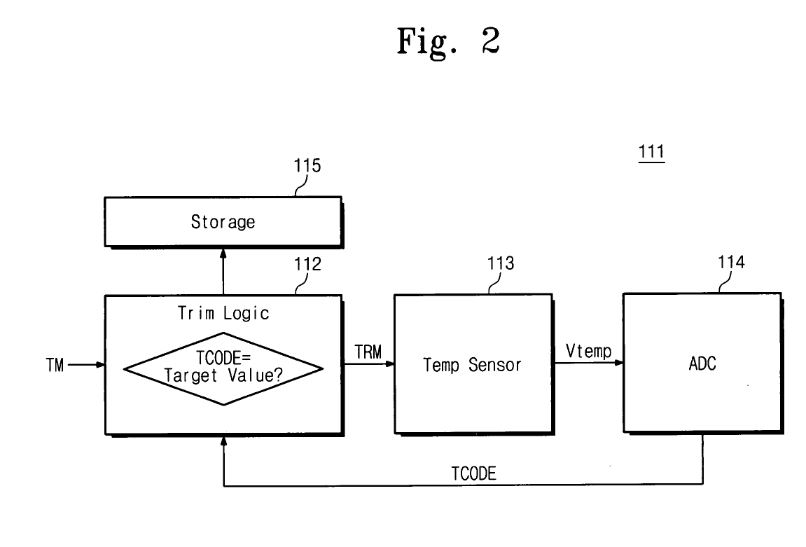

By using the calculated trim values, the offset of the temperature compensator may be changed, or a correction value according to temperature is regulated upon driving of the nonvolatile memory. Detailed description thereof will be made with reference to FIGS. 2 through 4.

In a typical memory test system, the trim operations of the temperature compensators are performed with respect to a plurality of nonvolatile memories one by one. Also, the trim operation of the temperature compensator of the nonvolatile memory is performed through repeated regulation and measurement of the trim value by an external tester to match a target value. The above trimming method of the temperature compensator takes a large amount of time to test a chip. Accordingly, the typical method has mass production limitations.

By contrast, the memory test system 10 according to an example embodiment may include a plurality of non-volatile memories 110, 120, 130, . . . , 160 including a temperature compensator automatically performing a trim operation during test operation. Thus, the plurality of nonvolatile memories 110, 120, 130, . . . , 160 may perform simultaneous and in parallel trim operations of temperature compensators 111, 121, 131, . . . , 161 in response to a test signal TM. Subsequently, the memory test system according to the example embodiment may require less time for testing memories compared to typical systems, and may have the advantage of mass production.

The nonvolatile memories 110, 120, 130, . . . , 160 may include NAND flash memories, NOR flash memories, MRAM, FRAM, and PRAM that may maintain data although powered off. In particular, the nonvolatile memories 110, 120, 130, . . . , 160 may include a memory having a Multi Level Cell (MLC) that stores a plurality of bits in a cell.

FIG. 2 is a diagram illustrating the temperature compensator of FIG. 1 according to an example embodiment. Referring to FIG. 2, a temperature compensator 111 may include a trim logic circuit 112, a temperature sensor 113, an analog-digital converter 114, and a storage 115.

The trim logic circuit 112 may generate a trim value TRM for controlling an offset of the temperature sensor 113 in response to a trim signal TM. A target value may be a digital value corresponding to an offset value of the temperature sensor 113 determined by a user. For example, the target value may be a digital value corresponding to an offset value of the temperature sensor 113 desired by a user. The target value may be stored inside or outside the trim logic circuit 112.

The trim logic circuit 112 may compare the target value with a temperature code TCODE delivered from the analog-digital converter 114. The trim logic circuit 112 may increase the trim value TRM according to a result of the comparison.

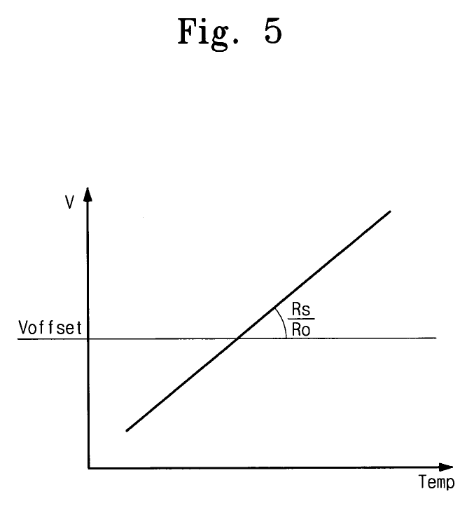

The temperature sensor 113 may output an analog temperature voltage Vtemp to perform compensation of the nonvolatile memory according to temperature. The temperature sensor 113 may perform a trimming on an offset voltage in response to the trim value TRM generated from the trim logic circuit 112. Detailed description thereof will be made with reference to FIG. 5.

The analog-digital converter 114 may generate a temperature code TCODE that is digitized from the temperature voltage Vtemp from the temperature sensor 113 to output to the trim logic circuit 112.

The storage 115 may store a corresponding trim value TRM when the temperature code TCODE matches the target value. The trim value TRM stored in the storage 115 may be used to perform EFUSE setting or laser cutting of the temperature sensor 113. For example, the trim value TRM stored in the storage 115 may be used to regulate an actual trim value of the temperature sensor 113. For this, the trim value stored in the storage 115 may be externally output.

The trim value TRM stored in the storage 115 may also be used as internal trim data of the nonvolatile memory. For example, the trim value TRM may be read from the storage 115 to be used as trim data. The trim data TRM stored in the storage 115 may be stored as non-active fuse data in the nonvolatile memory.

The temperature compensator illustrated in FIG. 2 may convert the temperature voltage Vtemp into a digital value and compare the values, but example embodiments are not limited thereto. The temperature compensator may be implemented to compare the analog temperature voltage Vtemp with a reference value.

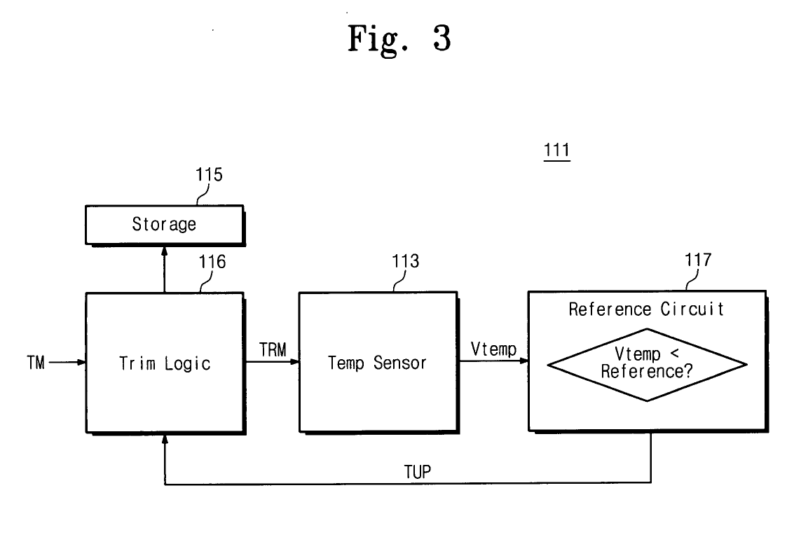

FIG. 3 is a diagram illustrating the temperature compensator of FIG. 1 according to an example embodiment. Referring to FIG. 3, a temperature compensator 111 may include a temperature sensor 113, a storage 115, a trim logic circuit 116, and a reference circuit 117.

The trim logic circuit 116 may transmit an initial trim value for regulating an offset of the temperature sensor 113 in response to a test signal TM. The trim logic circuit 116 may increase a trim value TRM in response to a trim-up signal TUP output from the reference circuit 117, and outputs an increased trim value TRM to the temperature sensor 113.

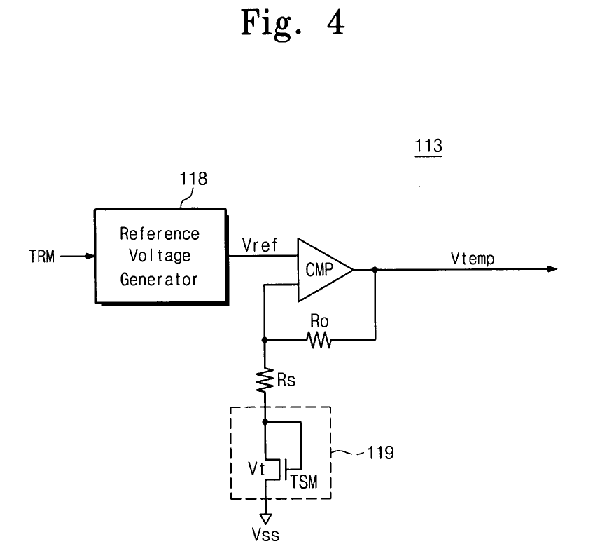

The temperature sensor 113 may regulate an offset voltage in response to the trim value TRM output from the trim logic circuit 116. A method of regulating the offset voltage regulation by the temperature sensor 113 will be described with reference to FIG. 4.

The reference circuit 117 may determine whether a temperature voltage Vtemp is less than a reference value. According to a result of the determination, a trim-up signal TUP may be generated. The trim value may be increased according to the generated trim-up signal TUP.

FIG. 4 is a diagram illustrating a temperature sensor according to an example embodiment. Referring to FIG. 4, the temperature sensor 113 may include a reference voltage generator 118, a comparator CMP, a slop resistor Rs, an offset resistor Ro, and a temperature-sensing transistor 119. The reference voltage generator 118 may generate a reference voltage Vref corresponding to a received trim value TRM.

The offset resistor Ro may be connected between an output terminal and an input terminal of the comparator CMP. The slop resistor Rs may be connected between the input terminal of the comparator CMP and a drain of the temperature-sensing transistor 119. The temperature-sensing transistor 119 may include a gate connected to the drain, and a source connected to a ground voltage Vss. The temperature sensor 113 may generate a reference voltage Vref according to a trim value TRM, and output a temperature voltage Vtemp corresponding to the reference voltage Vref. The output temperature voltage Vtemp may include an offset of the temperature sensor 113.

The temperature sensor 113 may change a threshold voltage Vt of the temperature-sensing transistor 119 according to temperature and compare the threshold voltage Vt with the reference voltage Vref according to changes of the threshold voltage Vt to regulate the output temperature voltage Vtemp. The output temperature voltage Vtemp is expressed as

$$\begin{matrix}Equation ( 1 ) & \\ Vtemp = ( 1 + \frac{Ro}{Rs} ) Vref - \frac{Ro}{Rs} Vt & Equation ( 1 )\end{matrix}$$

Referring to FIG. 1, when temperature is constant, the temperature voltage Vtemp may linearly increase with respect to the reference voltage Vref. Accordingly, the reference voltage Vref in response to the trim value TRM.

FIG. 5 is a diagram illustrating regulation of an offset voltage of the temperature sensor of FIG. 4. Referring to FIGS. 4 and 5, regulating the offset voltage of the temperature sensor may consider only the change of a voltage offset according to temperature.

Typically regulating the offset voltage must consider at least the variation with respect to offset and the gradient between two points relevant to voltage with temperature. Accordingly, a process of calculating a trim value corresponding to a target offset voltage takes much time by scanning two points in turn.

By contrast, regulating the offset voltage according to an example embodiment may consider only the variation with respect to the offset voltage under the assumption that gradients of all chips according to temperature (for example, the rate of increase Ro/Rs) are identical. Thus, time for calculating a trim value for a target offset voltage may be reduced.

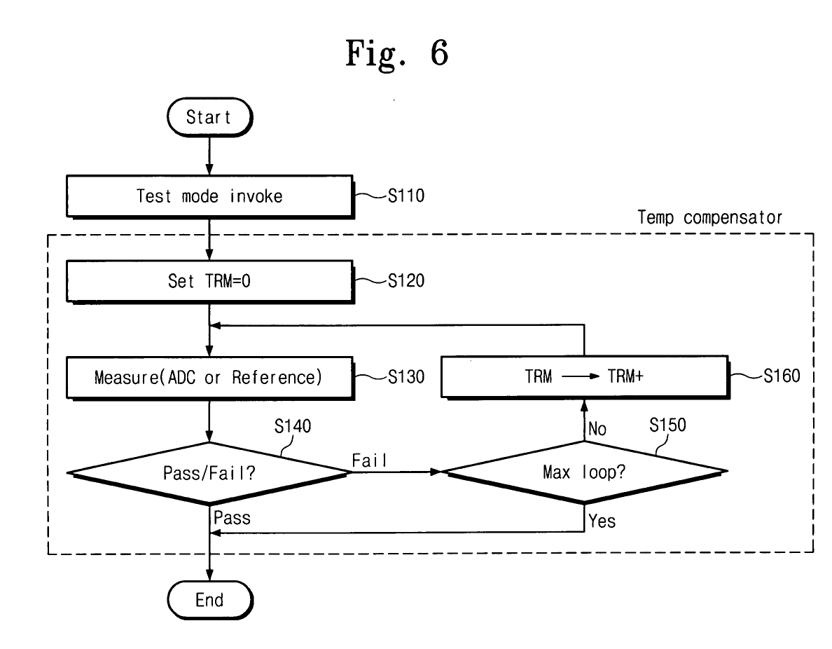

FIG. 6 is a flowchart illustrating a method of calculating a trim value of a temperature compensator in a memory test system according to an example embodiment. Referring to FIGS. 1, 2, and 4, the method is performed as follows.

In operation S110, a tester 200 transmits a test signal TM to each nonvolatile memories 110, 120, 130, . . . , 160. The test signal TM is a signal for putting the nonvolatile memories 110, 120, 130, . . . , 160 into a test mode. Each of temperature compensators 111, 121, 131, . . . , 161 of the nonvolatile memories 110, 120, 130, . . . , 160 automatically calculates a trim value TRM in response to the test signal TM as below.

In operation S120, a trim logic circuit 112 receives a test signal TM, and transmits an initial trim value (TRM=0) to a temperature sensor 113. The temperature sensor 113 outputs an offset voltage Vtemp according to the initial trim value (TRM=0). Here, the outputted offset voltage Vtemp is an analog value, and is an actual offset value of the temperature sensor 113. The outputted offset voltage Vtemp is converted into a digital value by an analog-digital converter 114.

In operation S130, the analog offset voltage Vtemp of the temperature sensor 113 is measured. A method of measuring the offset voltage Vtemp is not limited only to analog-to-digital value conversion as described in FIG. 2. As described in FIG. 3, the offset voltage Vtemp may be measured by comparing the analog offset voltage Vtemp with a reference value.

In operation S140, the trim logic circuit 112 determines whether a temperature code TCODE obtained by converting the offset voltage Vtemp into a digital value is identical to a target value. The target value is an offset value of the temperature sensor 113 desired by a user.

If the temperature code TCODE is not identical to the target value, in operation S150, the trim logic circuit 112 determines whether a trim loop is maximum. If the trim loop is not maximum, in operation S160, the trim logic circuit 112 increases the trim value. If the trim loop is maximum, the trim logic circuit 112 stops the trim operation. Thus, the calculation operation of the trim value is completed. The trim logic circuit 112 includes a circuit for restricting the maximum number of loops so as not to be trapped in an infinite loop.

If the temperature code TCODE is identical to the target value, the trim logic circuit 112 stores a corresponding trim value in a storage 115. Thus, the calculation operation of the trim value is completed. The stored trim value is used as trim data during power-up operation, or used as data necessary to perform EFUSE cutting for an actual trim regulation.

The above calculation operation of a trim value is simultaneously performed in all nonvolatile memories 110, 120, 130, . . . , 160 that enter a test mode. With this parallel test, test time may be reduced.

A temperature compensator according to an example embodiment may automatically find and store a trim value for correcting an offset during test operation. Accordingly, nonvolatile memories including the temperature compensator may simultaneously perform parallel trim processes on each memory during test operation, thereby reducing test time.

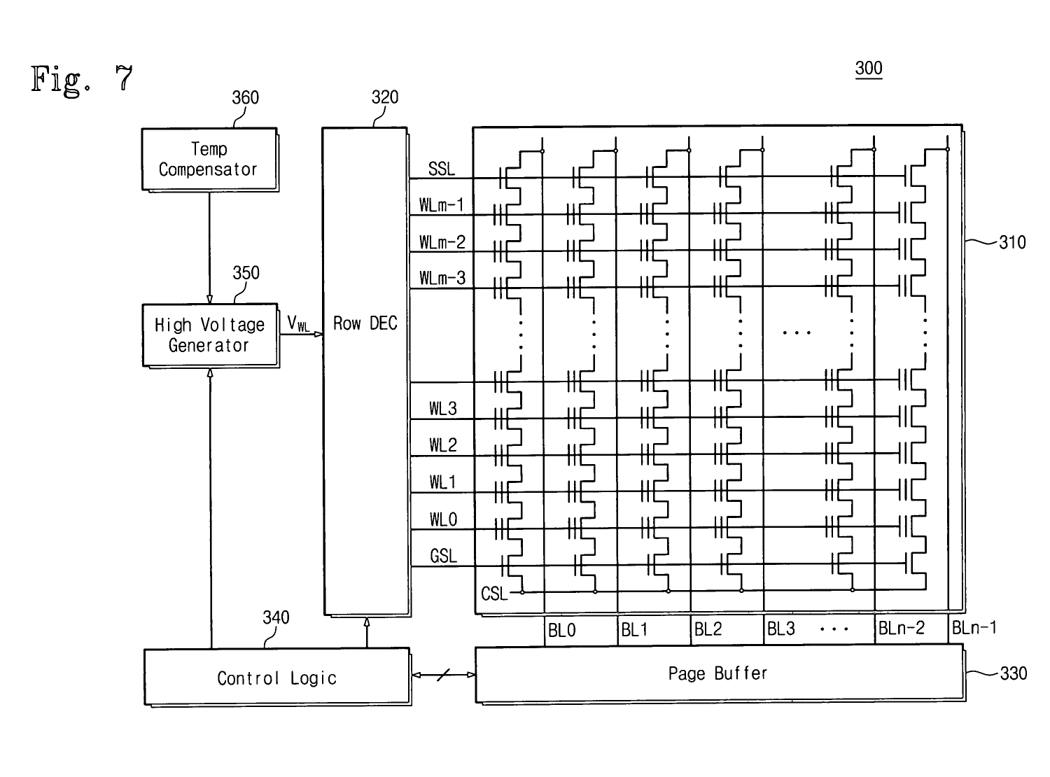

FIG. 7 is a diagram illustrating a NAND flash memory having a temperature compensator according to an example embodiment. Referring to FIG. 7, a NAND flash memory 300 may include a memory cell array 310, a row decoder 320, a page buffer 330, a control logic 340, a high voltage generator 350, and a temperature compensator 360. The temperature compensator 360 may compensate a word line voltage V_{WL} generated from the high voltage generator 350 according to temperature.

The memory cell array 310 may include a plurality of bit lines BL0 to BLn-1 and a plurality of word lines WL0 to WLm-1, and a plurality of memory cells in a cross-region between the bit lines and the word lines. Multi bit data may be stored in each of the memory cells. The memory cell array 310 may include a plurality of memory blocks.

The row decoder 320 may select a memory block according to an inputted address, and selects a word line to be driven in the selected memory block. For example, the row decoder 320 may decode an address during program operation to select a word line to be driven in the selected memory block. A program voltage may be applied from the high voltage generator 350 to the selected word line.

The page buffer circuit 330 may include a plurality of page buffers temporarily storing data loaded to the memory cell array 310 during a program operation, or temporarily storing data read from the memory cell array 310 during read operation. Page buffers may be connected to the memory cell array 310 through corresponding bit lines BL0 to BLn-1.

The control logic 340 may generate a control signal to control all operations of internal elements during a program/read/delete operation.

The high voltage generator 350 may generate a word line voltage V_{WL} necessary for the program/read/delete operation. The high voltage generator 350 may compensate a word line voltage V_{WL} according to a compensation value delivered from the temperature compensator 360.

The temperature compensator 360 may determine the compensation value of the word line voltage V_{WL} according to temperature to deliver to the high voltage generator 350.

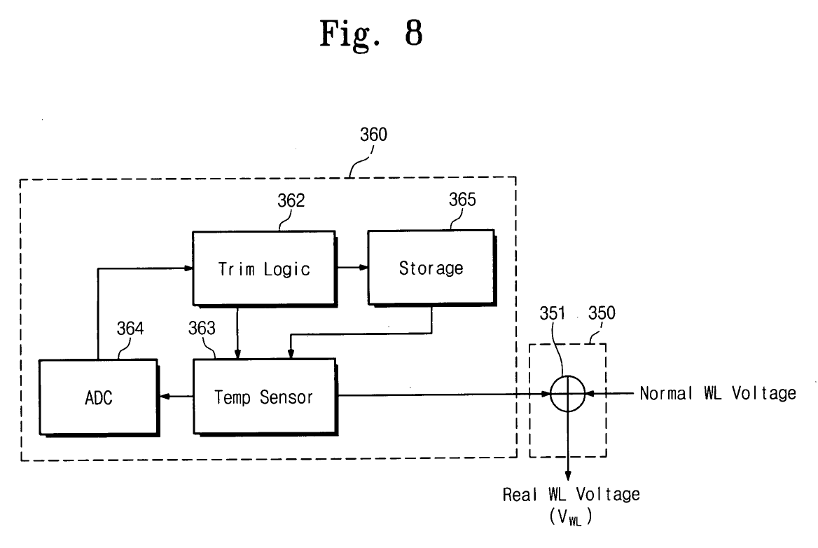

FIG. 8 is a diagram illustrating an example of using the temperature compensator of FIG. 7 according to an example embodiment. Referring to FIGS. 7 and 8, a NAND flash memory 300 may include a temperature compensator 360 including an adder 351 of a high voltage generator 350, a trim logic circuit 362, a temperature sensor 363, an analog-digital converter 364, and a storage 365.

The trim logic circuit 362 may automatically find a trim value matching an offset voltage of the temperature sensor 363 during wafer level test operation of the NAND flash memory 300, and store the found trim value in the storage 365. The temperature sensor 363 may output a correction value according to temperature upon driving of the NAND flash memory 300 to the adder 351. The correction value may include a correction of the offset voltage according to the trim value stored in the storage.

The adder 351 may add a normal word line voltage and the correction value of the temperature sensor 363 to generate an actual word line voltage V_{WL}. The corresponding relation between temperature and the correction value may be stored in a lookup table.

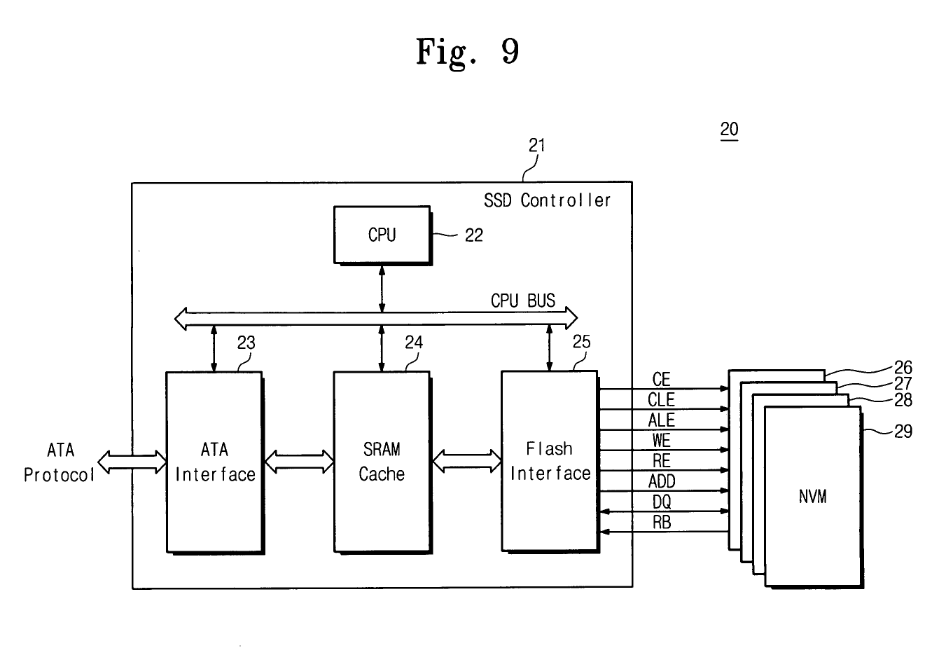

FIG. 9 is a diagram illustrating a Solid State Drive (SSD) system including a flash memory device 20 according to an example embodiment. Referring to FIG. 9, a SSD system may include a SSD controller 21, and flash memories 26 to 29. The flash memories 26 to 29 may include temperature compensators according to an example embodiment.

The memory system according to an example embodiment may be applied to SSDs. Recently, SSDs are attracting attention as a next generation memory instead of Hard Disk Drive (HDD). SSD is a data storage device using a memory chip, e.g., a flash memory, to store data instead of rotating disks used in HDDs. Compared to mechanically driven HDDs, SSDs may have advantages in terms of speed, shock-resistance, and low power consumption.

Referring again to FIG. 9, a Central Processing Unit (CPU) 22 may receive a command from a host, and determine whether to store data from the host in a flash memory or to transmit data stored in the flash memory to the host. An Advanced Technology Attachment (ATA) interface 23 may exchange data with the host under the control of the CPU 22. The ATA interface 23 patches a command and an address from the host to deliver to CPU 22 through a CPU bus. The ATA interface 23 may include, e.g., Serial-ATA (SATA), Parallel-ATA (PATA), and External SATA (ESATA) interfaces. Data received from a host through the ATA interface 23 or transmitted to the host are delivered through a SRAM cache 24 without passing a CPU bus under the control of the CPU 22.

The SRAM cache 24 may temporarily store data moved between the host and the flash memories 26 to 29. The SRAM cache 24 may store a program to be run by the CPU 22. The SRAM cache 24 may be considered a buffer memory, and does not necessarily include a SRAM. A flash interface 25 may exchange data with nonvolatile memories used as a storage device. The flash interface 25 may be configured to support, e.g., a NAND flash memory, a One-NAND flash memory, and a multi-level flash memory.

A memory system according to an example embodiment may be used as a portable storage device. Accordingly, the memory system may be used as a storage device in MP3s, digital cameras, PDAs, e-books, digital TVs, and computers.

The memory system or the storage device may be mounted in various package types. For example, the memory system or the storage device may be mounted using packages such as Package on Package (PoP), Ball Grid Arrays (BGAs), Chip Scale Packages (CSPs), Plastic Leaded Chip Carrier (PLCC), Plastic Dual In-Line Package (PDIP), Die in Waffle Pack, Die in Wafer Form, Chip On Board (COB), Ceramic Dual In-Line Package (CERDIP), Plastic Metric Quad Flat Pack (MQFP), Thin Quad Flatpack (TQFP), Small Outline (SOIC), Shrink Small Outline Package (SSOP), Thin Small Outline (TSOP), Thin Quad Flatpack (TQFP), System In Package (SIP), Multi Chip Package (MCP), Wafer-level Fabricated Package (WFP), and Wafer-Level Processed Stack Package (WSP).

Because a plurality of nonvolatile memories may include a temperature compensator automatically calculating a trim value during a test mode, the memory system according to the example embodiments may reduce typical test time for the memories.

The above-disclosed subject matter is to be considered illustrative, and not restrictive, and the appended claims are intended to cover all such modifications, enhancements, and other embodiments, which fall within the true spirit and scope of the example embodiments. Thus, to the maximum extent allowed by law, the scope of the example embodiments is to be determined by the broadest permissible interpretation of the following claims and their equivalents, and shall not be restricted or limited by the foregoing detailed description.

While example embodiments have been particularly shown and described, it will be understood by one of ordinary skill in the art that variations in form and detail may be made therein without departing from the spirit and scope of the claims.

What is claimed is:

1. A nonvolatile memory device, comprising:
a temperature compensator configured to calculate a trim value for regulating a characteristic of the nonvolatile memory device that varies with temperature in response to a test signal.

2. The nonvolatile memory device of claim 1, wherein the temperature compensator comprises:
a trim logic circuit configured to receive the test signal and calculate the trim value; and
a temperature sensor configured to generate a voltage based on the trim value and a sensed temperature, wherein
the trim logic circuit increases the trim value until the voltage is equal to a target value.

3. The nonvolatile memory device of claim 2, wherein the temperature compensator further comprises:
an analog-digital converter configured to convert the voltage into a digital value; and
a storage configured to store the trim value if the digital value is equal to a target digital value corresponding to the target value, wherein the trim logic circuit increases the trim value if the digital value is not equal to the target digital value corresponding to the target value.

4. The nonvolatile memory device of claim 3, further comprising:
a control logic circuit configured to generate a control signal to control operations associated with a program operation, a read operation and a delete operation of the nonvolatile memory device; and
a high voltage generator configured to generate a word line voltage based on the control signal, the word line voltage being for one of the program operation, the read operation and the delete operation, wherein the high voltage generator compensates the word line voltage based on the trim value.

5. The nonvolatile memory device of claim 2, wherein the temperature compensator further comprises:
a reference circuit configured to generate a trim up signal based on the voltage and a reference value corresponding to the target value, wherein the trim logic circuit increases the trim value based on the trim up signal.

6. The nonvolatile memory device of claim 5, wherein the temperature compensator further comprises:
a storage configured to store the trim value.

7. The nonvolatile memory device of claim 6, wherein the reference circuit generates the trim up signal if the voltage is less than the reference value.

8. The nonvolatile memory device of claim 6, wherein the reference circuit does not generate the trim up signal and the trim value is stored in the storage if the voltage equals the reference value.

9. The nonvolatile memory device of claim 5, further comprising:
a control logic circuit configured to generate a control signal to control operations associated with a program operation, a read operation and a delete operation of the nonvolatile memory device; and
a high voltage generator configured to generate a word line voltage based on the control signal, the word line voltage being for one of the program operation, the read operation and the delete operation, wherein the high voltage generator compensates the word line voltage based on the trim value.

10. The nonvolatile memory device of claim 2, wherein the trim logic circuit increases the trim value less than a threshold number of times.

11. The nonvolatile memory device of claim 2, wherein the temperature sensor comprises:
a reference voltage generator configured to generate a reference voltage corresponding to the trim value; and
a comparator configured to generate the voltage based on the reference voltage and a threshold voltage that varies with temperature.

12. The nonvolatile memory device of claim 11, wherein the threshold voltage is a threshold voltage of a temperature-sensing transistor that varies according to temperature.

13. The nonvolatile memory device of claim 1, wherein the nonvolatile memory device comprises:
a NAND flash memory, wherein the temperature compensator corrects a word line voltage of the NAND flash memory according to temperature.

14. The nonvolatile memory device of claim 1, wherein the trim value is calculated during a wafer level test operation.

15. The nonvolatile memory device of claim 1, wherein
the nonvolatile memory device is one of a plurality of nonvolatile memory devices; and
the test signal is applied to each of the plurality of nonvolatile memory devices in parallel in order to calculate the trim value for each of the plurality of nonvolatile memory devices at a same time.

16. The nonvolatile memory device of claim 1, wherein the characteristic of the nonvolatile memory device that varies with temperature is one of a program voltage, a read voltage and a delete voltage.

17. A memory system, comprising:
a plurality of nonvolatile memory devices including a temperature compensator configured to calculate a trim value for regulating a characteristic of the nonvolatile memory device that varies with temperature in response to a test signal; and
a memory controller configured to control the nonvolatile memory device.

18. The memory system of claim 17, wherein the memory controller comprises:
a processor configured to receive a command from a host, and configured to determine whether to one of store data from the host in the plurality of nonvolatile memory devices and to transmit data stored in the plurality of nonvolatile memory devices to the host;
a bus interface configured to exchange data with the host under the control of the processor;
a memory cache configured to temporarily store data moved between the host and the plurality of nonvolatile memory devices; and
a memory interface configured to exchange data between the controller and the plurality of nonvolatile memory devices.

19. A memory test system, comprising:
a plurality of nonvolatile memories, each including a temperature compensator; and
a tester configured to test the plurality of nonvolatile memories, wherein the temperature compensator calculates a trim value for regulating a characteristic of the plurality of nonvolatile memories that varies with temperature in response to a test signal.

20. The memory test system of claim 19, wherein the tester applies the test signal to each of the plurality of nonvolatile memories in parallel in order to calculate the trim value for each of the plurality of nonvolatile memories at a same time.
